(19) United States
(12) Patent Application Publication
(10) Pub. No.: US 2011/0298528 A1
(43) Pub. Date: Dec. 8, 2011

(54) POWER SEMICONDUCTOR SYSTEM

(75) Inventors: Koichi Endo, Tokyo (JP); Yukio Tsunetsugu, Fukuoka-ken (JP); Kazutoshi Nakamura, Kanagawa-ken (JP)

(73) Assignee: KABUSHIKI KAISHA TOSHIBA, Tokyo (JP)

(21) Appl. No.: 13/052,269

(22) Filed: Mar. 21, 2011

(30) Foreign Application Priority Data
Jun. 7, 2010 (JP) 2010-129663

(51) Int. Cl. H03K 3/011

(52) U.S. Cl. 327/512

(57) ABSTRACT

According to one embodiment, a power semiconductor system includes; a first power semiconductor element, a driver IC, a first temperature detection element, a control circuit and an overheat protection control section. The first power semiconductor element controls current flowing between a first electrode and a second electrode with a control electrode. The driver IC supplies a drive signal making the first power semiconductor element on and off. The first temperature detection element detects a temperature of the driver IC. The control circuit supplies a control signal for controlling operation of the driver IC to the driver IC. The overheat protection control section is configured to supply an overheat protection signal to the control circuit based on an output of the first temperature detection element. The control circuit performs overheat protection operation. The overheat protection control section supplies the overheat protection signal to the control circuit.

### CROSS-REFERENCE TO RELATED APPLICATIONS

This application is based upon and claims the benefit of priority from the prior Japanese Patent Application No. 2010-129663, filed on Jun. 7, 2010; the entire contents of which are incorporated herein by reference.

### FIELD

Embodiments described herein relate generally to a power semiconductor system.

### BACKGROUND

In a DC-DC converter used for a power supply of a personal computer, a home electric appliance, etc., an inverter used for motor control, and the like, a power semiconductor system is configured including a control circuit, a driver IC, a power semiconductor element, and the like, for performing switching control. For the power semiconductor element, there is used a high voltage MOSFET (Metal Oxide Semiconductor Field Effect Transistor), for example. Then, a power semiconductor device called a MCM (Multi Chip Module) is sometimes formed which includes a high-side MOSFET, a low-side MOSFET, and a driver IC for turning on and off the gate electrodes of these MOSFETs, within the same resin package. A DC-DC convertor may be specified as an example of the power semiconductor system configured with this MCM, the control circuit for controlling the driver IC within the MCM, and other control sections. The control circuit and the other control sections are sometimes incorporated within the MCM.

In the MCM, the power semiconductor element and the driver IC are disposed so as to neighbor to each other as different chips and separately disposed with resin interposed therebetween within a resin package. Further, both of the elements are sometimes disposed monolithically within the same chip and the single chip is packaged with resin to form a power semiconductor device instead of the MCM. To the output terminal of the DC-DC converter, an arithmetic processing unit such as a CPU is connected as a load. When the load of the CPU changes abruptly, the output of the DC-DC convertor is required to provide a higher current abruptly. As a result, temperature of the high-side MOSFET in the DC-DC convertor increases abruptly and it is necessary to perform overheat protection control within the power semiconductor system so as to prevent the high-side MOSFET from exceeding a break down temperature due to this temperature rise.

### BRIEF DESCRIPTION OF THE DRAWINGS

FIG. 1 is a block diagram showing the main configuration of a power semiconductor system of an example 1;

FIG. 2 is a plan view showing an example of a packaged part of the main configuration of the power semiconductor system of the example 1;

FIG. 3 is a flowchart showing the overheat protection control of the power semiconductor system of example 1;

FIG. 4 is a graph showing temperature distributions on the power semiconductor device of the power semiconductor system of the example 1 during the operation;

FIG. 5 is a graph for describing the temperature detection level for the power semiconductor system of the example 1 in the steady state and the transient state;

FIG. 6 is a graph for describing the determination of the transient mode temperature detection level for the power semiconductor system of the example 1;

FIG. 7 is a block diagram showing the main configuration of a power semiconductor system of an example 2;

FIG. 8 is a plan view showing an example of a packaged part of the main configuration of the power semiconductor system of the example 2;

FIG. 9 is a flowchart showing the overheat protection control of the power semiconductor system of the example 2;

FIG. 10 is a graph for describing the temperature detection level for the power semiconductor system of the example 2 in the steady state and the transient state;

FIG. 11 is a graph for describing the determination of the transient mode temperature detection level for the power semiconductor system of the example 2;

FIG. 12 is a plan view showing an example of a packaged part of the main configuration of a power semiconductor system of a variation of the example 2;

FIG. 13 is a flowchart showing the overheat protection control of the power semiconductor system of the variation of the example 2;

FIG. 14 is a plan view showing an example of a packaged part of the main configuration of a power semiconductor system of an example 3;

FIG. 15 is a graph for describing the temperature detection level for the power semiconductor system of the example 3 in the steady state and the transient state; and

FIG. 16 is a plan view showing an example of a packaged part of the main configuration of a power semiconductor system of a variation of the example 3.

### DETAILED DESCRIPTION

In general, according to one embodiment, a power semiconductor system includes; a first power semiconductor element, a driver IC, a first temperature detection element, a control circuit and an overheat protection control section. The first power semiconductor element is configured to control current flowing between a first electrode and a second electrode with a control electrode. The driver IC is configured to supply a drive signal making the first power semiconductor element on and off. The first temperature detection element is configured to detect a temperature of the driver IC. The control circuit is configured to supply a control signal for controlling operation of the driver IC to the driver IC. The overheat protection control section is configured to supply an overheat protection signal to the control circuit based on an output of the first temperature detection element. The control circuit receives the overheat protection signal to perform overheat protection operation for protecting the first power semiconductor element. The overheat protection control section determines whether a temperature detection mode of the driver IC is a steady mode or a transient mode, and in the steady mode, supplies the overheat protection signal to the control circuit when a temperature measured by the first temperature detection element reaches a steady mode temperature detection level, and in the transient mode, supplies the overheat protection signal to the control circuit when a temperature measured by the first temperature detection element reaches a transient mode temperature detection level.

Hereinafter, various embodiments will be described with reference to the accompanying drawings. A drawing to be used in the description of the embodiments is an illustration for easy explanation and a shape, a dimension, a size relationship and the like of each element in the drawing are not always the same in actual implementation as those shown in the drawing and can be changed optionally. Note that, while a power semiconductor system of the embodiment will be described by the use of an example of a DC-DC convertor, the power semiconductor system is not limited thereto and the embodiments can be applied to the power semiconductor system including a system in general configured by using a power semiconductor device which packages a power semiconductor element and a driver IC in an integrated manner, such as an inverter.

### Working Example 1

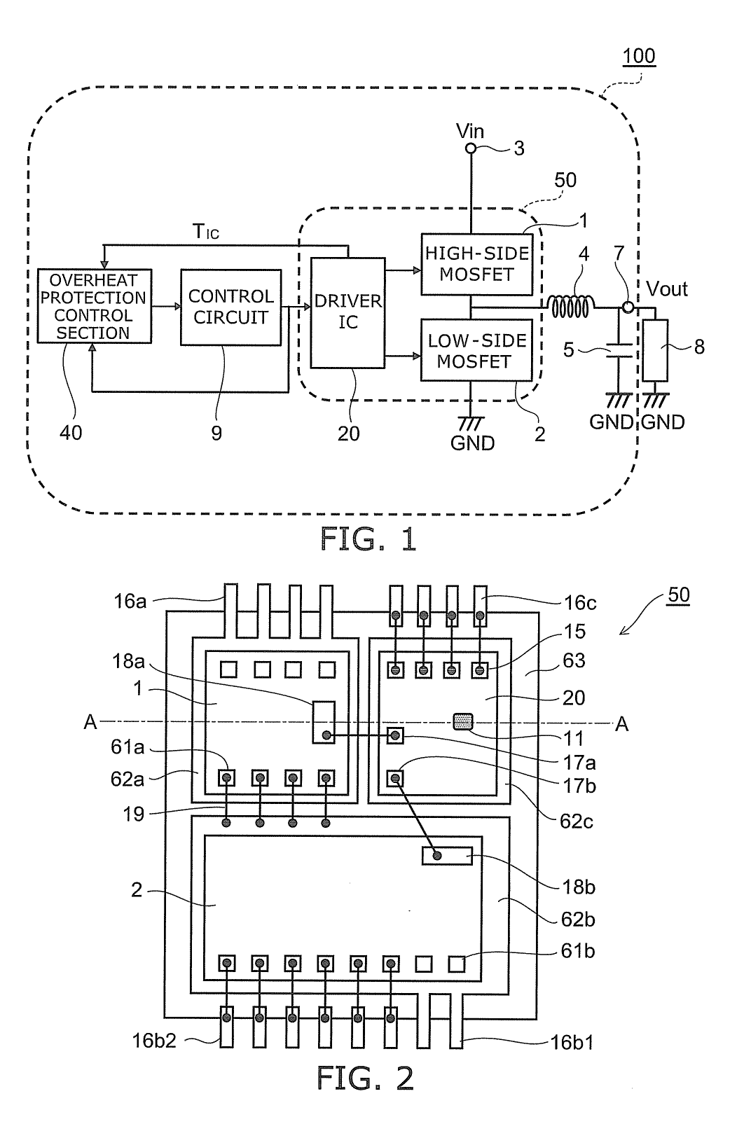

FIG. 1 is a block diagram showing the main configuration of a DC-DC convertor 100 which is an example of a power semiconductor system of a working example 1.

FIG. 2 is a plan view showing an example of a packaged part of the main configuration in the DC-DC convertor 100 which is an example of the power semiconductor system of the working example 1.

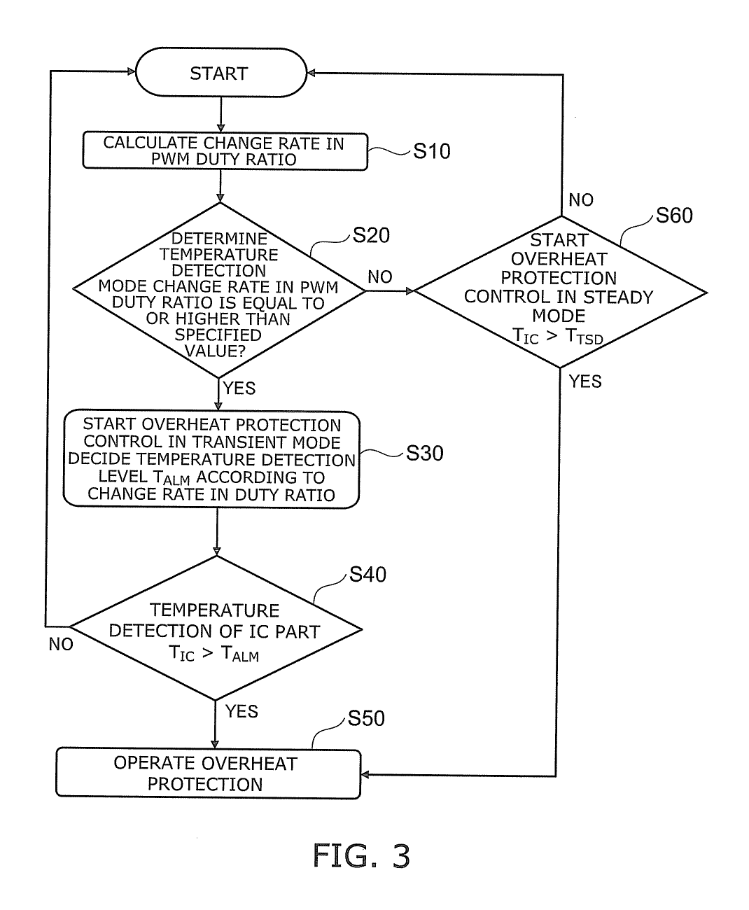

FIG. 3 is a flowchart showing overheat protection control of the DC-DC convertor 100 the working example 1.

As shown in FIG. 1, the DC-DC convertor 100 of the working example 1 includes a first power semiconductor element 1, a second power semiconductor element 2, an input terminal 3 of the DC-DC convertor, an inductor 4, a capacitor 5, a ground terminal GND, an output terminal 7 of the DC-DC convertor, a driver IC 20, a control circuit 9, and an overheat protection control section 40. Note that, while an example of the power semiconductor element will be explained for a case in which an n-channel MOSFET is used, it is possible to use an IGBT (Insulated Gate Bipolar Transistor) and other power semiconductor devices. This is the same in all the working examples hereinafter.

An n-channel high-side MOSFET 1 (first power semiconductor element) and an n-channel low-side MOSFET 2 (second power semiconductor element) are serially connected with each other between the input terminal 3 and the ground terminal GND. The source electrode (not shown in the drawing) of the low-side MOSFET 2 is connected to the ground terminal GND and the drain electrode (not shown in the drawing) of the low-side MOSFET 2 is connected to the source electrode (not shown in the drawing) of the high-side MOSFET 1. The drain electrode (not shown in the drawing) of the high-side MOSFET 1 is connected to the input terminal 3.

The source electrode (not shown in the drawing) of the high-side MOSFET 1 is connected to one end of the inductor 4. The other end of the inductor 4 is connected to the output terminal 7 of the DC-DC convertor. The other end of the inductor 4 is connected to one end of the capacitor 5, and the other end of the capacitor 5 is connected to the ground terminal GND.

In each of the high-side MOSFET 1 and the low-side MOSFET 2, the drain electrode (not shown in the drawing) is a first electrode and the source electrode (not shown in the drawing) is a second electrode, and the gate electrode (not shown in the drawing) which is an control electrode controls a current flowing from the drain electrode to the source electrode. The driver IC 20 supplies a gate signal and performs ON/OFF control of the gate electrode (not shown in the drawing) of the high-side MOSFET 1 and the gate electrode (not shown in the drawing) of the low-side MOSFET 2 in synchronization. Further, in order to avoid turning on both of the MOSFETs at the same time, driver IC 20 supplies the gate signal to each of the gate electrode of the high-side MOSFET 1 and the gate electrode of the low-side MOSFET 2.

The control circuit 9 supplies a PWM (Pulse Width Modulation) signal to the driver IC 20 as an output signal, and controls the gate signal to be supplied from the driver IC to each of the MOSFETs. The control circuit 9 detects an output voltage Vₒᵤₜ at the output terminal 7 of the DC-DC convertor with a comparator circuit which is not shown in the drawing, and performs the control of the operation of the driver IC 20 so as to increase a duty ratio of the PWM signal when Vₒᵤₜ reduces and so as to reduce the duty ratio of the PWM signal when Vₒᵤₜ increases.

The overheat protection control section 40 supplies an output signal to the control circuit 9. The driver IC 20 is provided with an IC part temperature detection element 11 which is a first temperature detection element, on the surface thereof as described below. The IC part temperature detection element 11 detects the temperature of the driver IC 20, and the driver IC 20 supplies a detection signal of the IC part temperature detection element 11 to the overheat protection control section 40. The IC part temperature detection element 11 detects the temperature rise in the driver IC 20 part which is caused by an abrupt current increase in the high-side MOSFET 1 or the low-side MOSFET 2, and thereby the overheat protection control section 40 detects the temperature rise in either of the MOSFETs. The overheat protection control section 40 supplies the overheat protection signal as the output signal to the control circuit 9 so as to cause the current to be cut off in the high-side MOSFET 1 or the low-side MOSFET 2 when the overheat protection control section 40 determines that the temperature detected by the IC part temperature detection element 11 becomes equal to or higher than a specified value. For example, the overheat protection control section 40 supplies the overheat protection signal to the control circuit 9 so as to zero the duty ratio of the PWM signal from the control circuit 9.

In this manner, when the overheat protection control section 40 detects an abnormal temperature rise of the power semiconductor element via the IC part temperature detection element during the operation of the power semiconductor system, for example, the DC-DC convertor 100, the overheat protection control section 40 outputs the overheat protection signal to the control circuit 9 so as to cut off the current flowing in the power semiconductor element. The control circuit 9 receives the overheat protection signal to control the operation of the driver IC, and thus the current flowing the power semiconductor element is cut off. The sequential control in this manner is defined as overheat protection control and the operation of controlling the operation of the driver IC by the control circuit 9 and cutting off the current flowing in the power semiconductor element 1 is defined as overheat protection operation. By the supply of the PWM signal from the control circuit 9 to the overheat protection control section 40, the overheat protection control section 40 can monitor the drive situation of the low-side MOSFET 2 together with that of the high-side MOSFET 1.

In the DC-DC convertor 100 of the working example, the high-side MOSFET 1, the low-side MOSFET 2, and the driver IC are included within the same resin package to form a power semiconductor device 50 as an MCM. FIG. 2 shows a plan view of the power semiconductor device 50. FIG. 2 shows a plan view omitting the resin which covers the surfaces of the driver IC 20, the high-side MOSFET 1, and the low-side MOSFET 2.

The drive IC 20 is disposed on a die pad 62c for the driver IC. A chip on which the high-side MOSFET 1 is formed is disposed on a die pad 62a for the high-side MOSFET. Further, a chip of the low-side MOSFET 2 is disposed on a die pad 62b for the low-side MOSFET so as to extend in a direction parallel to the direction along which the driver IC 20 and the high-side MOSFET 1 are disposed and so as to neighbor these chips.

The high-side MOSFET 1 is electrically connected to the die pad 62a for the high-side MOSFET via the drain electrode (not shown in the drawing), and provided with a source electrode pad 61a and a gate electrode pad 18a on the surface of the high-side MOSFET 1 opposite to the die pad 62a. While details are omitted, the source electrode pad 61a is electrically connected to the source electrode (not shown in the drawing), and the gate electrode pad 18a is electrically connected to the gate electrode (not shown in the drawing).

The low-side MOSFET 2 is electrically connected to the die pad 62b for the low-side MOSFET 2 via the drain electrode (not shown in the drawing), and provided with a source electrode pad 61b and a gate electrode pad 18b on the surface of the low-side MOSFET 2 opposite to the die pad 62b. The source electrode pad 61b is electrically connected to the source electrode (not shown in the drawing) and the gate electrode pad 18b is electrically connected to the gate electrode (not shown in the drawing).

An input/output electrode pad 15 for an input/output signal is provided on the chip surface of the driver IC 20. A gate output electrode pad 17a for the high-side MOSFET 1 and a gate output electrode pad 17b for the low-side MOSFET 2 are further provided on the surface thereof for supplying gate outputs to the gate electrodes (not shown in the drawing) of the high-side MOSFET 1 and the low-side MOSFET 2, respectively.

The resin package 63 is formed so as to be filled among the above three die pads separated from each other and among the driver IC 20, the high-side MOSFET 1, and the low-side MOSFET 2, and so as to cover the driver IC 20, the high-side MOSFET 1, and the low-side MOSFET 2.

A lead 16a integrated with the die pad 62a for the high-side MOSFET 1 is provided to protrude from the resin package 63 for leading out the drain electrode of the high-side MOSFET 1 to the outside of the resin package 63. The lead 16a is electrically connected to the input terminal 3. The source electrode pad 61a of the high-side MOSFET 1 and the die pad 62b for the low-side MOSFET 2 are electrically joined to each other with a bonding wire 19, and thereby the source electrode (not shown in the drawing) of the high-side MOSFET 1 and the drain electrode (not shown in the drawing) of the low-side MOSFET 2 are electrically connected to each other. A lead 16b1 integrated with the die pad 62b for the low-side MOSFET 2 is formed so as to protrude from the resin package 63 for leading out the drain electrode (not shown in the drawing) of the low-side MOSFET 2 to the outside of the resin package 63. The lead 16b1 is electrically connected to the output terminal 7 via the inductor 4. A lead 16b2 is formed so as to be separated from the die pad 62b for the low-side MOSFET 2 and to protrude from the resin package 63 for leading out the source electrode (not shown in the drawing) of the low-side MOSFET 2 to the outside of the resin package 63. The source electrode pad 61b of the low-side MOSFET 2 and the lead 16b2 are electrically connected to each other with a bonding wire 19, and thereby the source electrode of the low-side MOSFET 2 is led out to the outside of the resin package. The lead 16b2 is electrically connected to the ground terminal GND.

A lead 16c is formed for taking out the input/output signal of the driver IC 20 to the outside of the resin package 63 so as to be separated from the die pad 62c for the driver IC 20 and to protrude from the resin package. This lead 16c and the input/output electrode pad 15 formed on the surface of the driver IC 20 are electrically connected to each other with a bonding wire, and thereby the input/output electrode is led out to the outside of the resin package. A part of the lead 16c is electrically connected to the control circuit 9 and another part is electrically connected to the overheat protection control section 40. The output of the IC part temperature detection element 11 to be described below is taken out to a part of the input/output electrode pad 15 via an interconnection which is not shown in the drawing and supplied to the overheat protection control section 40 via another part of the lead 16c. Alternatively, the output of the IC part temperature detection element 11 may be taken out directly to another part of the lead 16c with a bonding wire without via the input/output electrode pad 15. Also in the other working examples and variations to be described below, the output of the temperature detection element can be supplied to the overheat protection control section 40 in the manner described above. The gate output electrode pads 17a and 17b of the driver IC 20 are electrically connected to the gate electrode pad 18a of the high-side MOSFET 1 and the gate electrode pad 18b of the low-side MOSFET 2, respectively, with bonding wires 19, and thereby the driver IC 20 supplies gate signals to the respective MOSFETs.

Further, the IC part temperature detection element 11 (first temperature detection element) is provided on the surface of the driver IC 20 for detecting the temperature of the driver IC part. The temperature detection element to be used here may be provided with a method in which a diode made of poly-silicon, for example, is formed on an inter-layer insulating film formed on the chip surface of the driver IC 20 and the temperature is detected from a relationship between the temperature and the current of the diode. Further, as another example, the temperature detection element may be provided with a method in which a resistor made of poly-silicon is formed on the chip surface of the driver IC 20 via an inter-layer insulating film and temperature is detected from a relationship between a resistance value and the temperature. Any other device capable of detecting temperature from a relationship between the temperature and a device characteristic can be used as the temperature detection element. Note that, in the working example, the temperature detection element is formed on the chip surface of the driver IC 20. This is because an additional process is increased to result in a higher cost when the temperature detection element is formed on the surface of the power semiconductor element such as the high-side MOSFET.

While the die pad 62a for the high-side MOSFET 1 and the die pad 62c for the driver IC 20 are provided to be separated from each other as shown in FIG. 2 in the working example, both of the pads may be provided so as to be integrated. That is, the high-side MOSFET 1 and the driver IC 20 may be formed on the same die pad so as to be separated from each other. Alternatively, the high-side MOSFET 1 and the driver IC 20 further may be formed on the same chip monolithically.

Next, the operation of the DC-DC convertor 100 which is a power semiconductor system of the working example will be explained by the use of FIG. 3 to FIG. 5. FIG. 3 shows contents of the overheat protection control performed by the overheat protection control section 40 of the DC-DC convertor in a flowchart. When a load such as a CPU (Central Processing Unit) is connected to the output terminal of the DC-DC convertor of the working example as shown in FIG. 1 and consumes a high current in an overload state, the control circuit 9 increases the duty ratio of the PWM signal to be supplied to the driver IC 20 for maintaining the same output voltage of the DC-DC convertor. Thereby, an ON state ratio in the high-side MOSFET 1 is increased against the OFF state, and current I_{ds1} flowing in the high-side MOSFET 1 is increased. As a result, when the voltage between the source and drain of the high-side MOSFET 1 is denoted by V_{ds1}, power consumption I_{ds1}×V_{ds1} is increased in the high-side MOSFET 1. This increase of the power consumption becomes a heat source, and the temperature of the high-side MOSFET 1 is increased abruptly. It is necessary to perform the overheat protection control so as to prevent the high-side MOSFET 1 from exceeding a break down temperature of the element. That is, the overheat protection control section 40 of the working example has a protection function of detecting the temperature of the driver IC 20 using the IC part temperature detection element 11 and cutting off the current in the high-side MOSFET 1 when the temperature of the IC part becomes higher than the specified value.

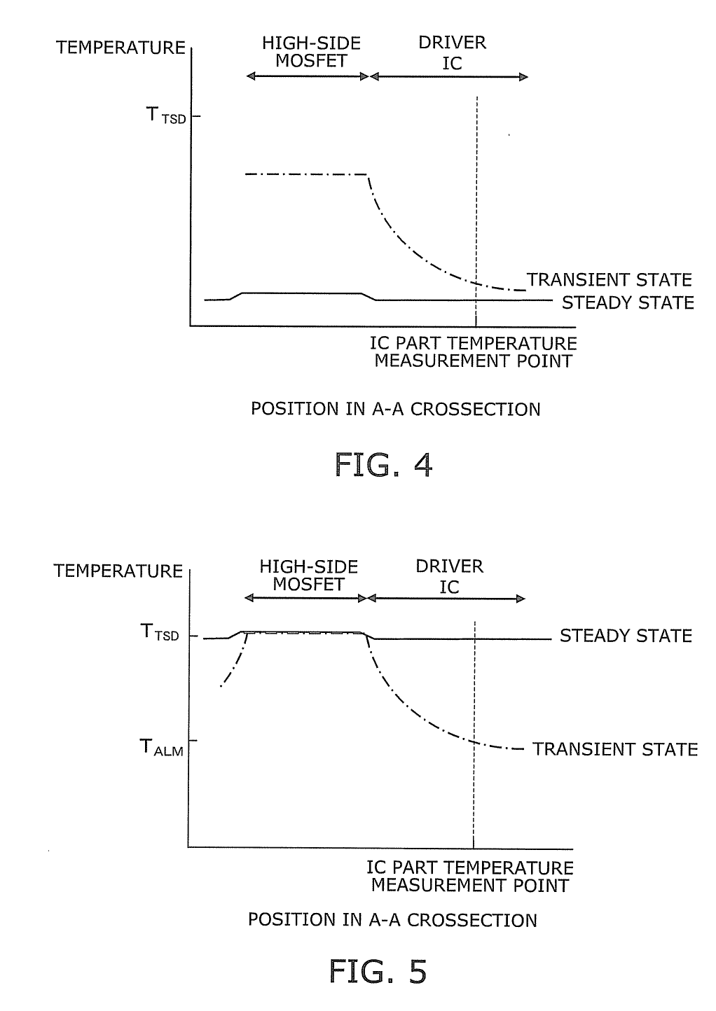

FIG. 4 is a graph showing temperature distributions on the chip surfaces of the high-side MOSFET 1 and the driver IC 20, respectively, in the direction of the dashed-dotted line A-A in FIG. 2. In a steady state where the load does not change abruptly, even when the high-side MOSFET 1 is overheated due to the overload, this heat is propagated and causes the temperature rise in the neighboring driver IC 20. If the temperature rise of the high-side MOSFET 1 is not abrupt against a heat resistance between the high-side MOSFET 1 and the driver IC 20, a temperature difference between the high-side MOSFET 1 and the driver IC 20 is approximately the same as shown by the solid line in FIG. 4. This state will be explained below as a temperature distribution in the steady state.

The temperature of the high-side MOSFET 1 has to be controlled so as to become not higher than an upper limit control temperature which is set to have a sufficiently large margin against the break down temperature. In the steady state where the load does not change abruptly (without load abrupt change), the temperature of the high-side MOSFET 1 and the temperature of the driver IC 20 are approximately the same, and therefore the overheat protection control section 40 outputs the overheat protection signal to the control circuit 9 and the control circuit 9 performs the overheat protection operation, when the IC part temperature detection element 11 detects a temperature as same as the above upper limit control temperature of the high-side MOSFET 1. The temperature detected at this time by the IC part temperature detection element 11 is defined as a steady mode temperature detection level T_{TSD}. Further, the temperature measurement when the overheat protection control section 40 measures the temperature of the driver IC 20 with the IC part temperature detection element by using the steady mode temperature detection level as criterion is defined as steady mode temperature detection.

Here, considering a case in which the load has changed abruptly (abrupt load change), temperature rises abruptly in the part of the high-side MOSFET 1 and a difference between the temperature in the high-side MOSFET 1 and the temperature at an IC part temperature measurement point of the driver IC 20 is increased as shown by the dashed-dotted line in the drawing. This state is called a transient state. In the transient state, from the IC part temperature measurement point toward the high-side MOSFET 1, the surface temperature of the driver IC 20 gradually rises and temperature abruptly rises around the high-side MOSFET 1. If the temperature detection is performed in the steady mode and the overheat protection control section 40 outputs the overheat protection signal and the control circuit 9 starts the overheat protection operation when the IC part temperature detection element 11 detects a temperature exceeding the steady mode temperature detection level, the high-side MOSFET 1 is broken down. Further, if the temperature detection level in the steady mode is set to be a sufficiently low level, the overheat protection control section 40 outputs the overheat protection signal and the control circuit 9 performs the overheat protection operation even when the overheat protection operation is not necessary in the steady state, resulting in a lower operation rate of the semiconductor device 50. In the power semiconductor system, highly efficient and reliable overheat protection control is desired to be performed.

In the working example, the overheat protection control section 40 is provided with a transient mode which detects the temperature in the abrupt load change state for solving this problem, in addition to the steady mode which detects the temperature in the steady state. There will be explained a method of performing the temperature detection and the overheat protection operation in this transient mode.

FIG. 5 is a graph comparing the temperature distribution in the direction of the dashed-dotted line A-A in FIG. 2 between the steady state and the transient state of the operation in the DC-DC convertor 100 when the temperature of the high-side MOSFET 1 reaches the upper limit control temperature. Since the temperature of the IC part temperature measurement point is approximately the same as the temperature of the high-side MOSFET 1 in the steady state as described above, the overheat protection control section 40 outputs the overheat protection signal and the control circuit 9 may perform the overheat protection operation when the temperature measured by the IC part temperature detection element 11 reaches the steady mode temperature detection level. On the other hand, in the transient state, the temperature of the IC part measurement point becomes T_{ALM} which is lower than the steady mode temperature detection level T_{TSD} as shown in FIG. 5. In the temperature detection of the transient mode, the overheat protection control section 40 needs to outputs the overheat protection signal and the control circuit 9 needs to perform the overheat protection operation when the temperature of the IC part temperature detection element 11 reaches T_{ALM}. The temperature T_{ALM} at this time is called a transient mode temperature detection level.

In the working example, first it is determined whether the temperature detection mode of the IC part temperature detection element 11 at the IC part temperature measurement point is the steady mode or the transient mode, and in the steady mode the overheat protection control section 40 outputs the overheat protection signal and the control circuit 9 performs the overheat protection operation when the temperature measured by the IC part temperature detection element 11 reaches the steady mode temperature detection level and in the transient mode when the temperature measured by the IC part temperature detection element 11 reaches the transient mode temperature detection level. In the determination whether the temperature detection mode is the steady mode or the transient mode, a parameter called an abrupt load change parameter is used. This parameter is defined as a parameter which changes within the DC-DC convertor when the load connected to the DC-DC convertor changes abruptly. For example, when the load has changed abruptly, the control circuit 9 increases a change rate in the duty ratio of the PWM signal. Further, a change rate of the electric power value calculated from the source-drain voltage and the source-drain current in the high-side MOSFET 1 changes abruptly. Alternatively, when the load has changed abruptly, the temperature of the chip surface of the driver IC 20 rises from the IC part temperature measurement point toward the high-side MOSFET 1 as shown in FIG. 4. This temperature rise also can be used as the abrupt load change parameter. Any other parameter which changes according to the abrupt load change within the DC-DC convertor can be used as the abrupt load change parameter. In the working example, there will be explained a case of using the change rate in the duty ratio of the PWM signal as the abrupt load change parameter.

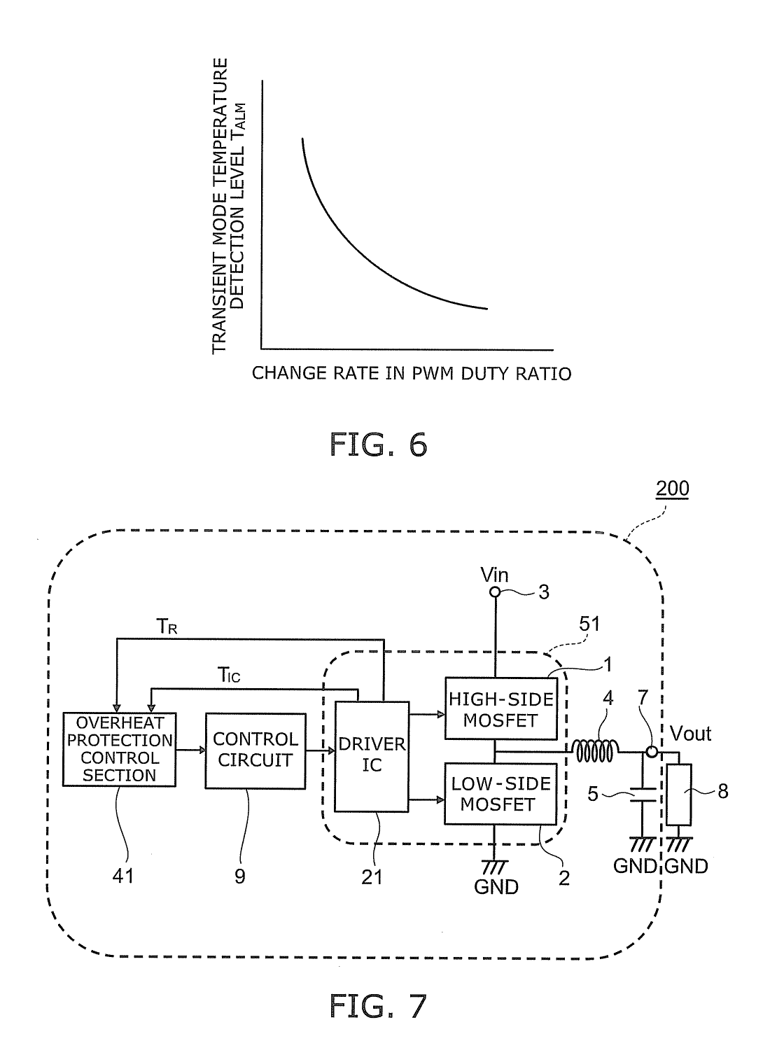

The temperature difference between the temperature of the high-side MOSFET 1 and the temperature of the IC part temperature measurement point changes according to the extent of the abrupt load change state. The abrupt load change parameter reflects the extent of the abrupt load change state. As the value of the abrupt load change parameter is larger, the extent of the abrupt load change state is larger. That is, in the case of the working example, when the load is increased abruptly and the current consumption becomes higher, the control circuit 9 increases the duty ratio of the PWM signal abruptly and increases the change rate thereof compared to the steady state, for maintaining the same output voltage of the DC-DC converter, resulting in the abrupt temperature rise in the high-side MOSFET 1. Accordingly, the transient mode temperature detection level T_{ALM} at which the overheat protection control section 40 outputs the overheat protection signal and the control circuit 9 performs the overheat protection operation should have a low value. As the extent of the abrupt load change is larger, the change rate in the duty ratio of the PWM signal which is the abrupt load change parameter is increased and the transient mode temperature detection level T_{ALM} should be set to be lower. FIG. 6 shows a relationship between the change rate in the duty ratio and the transient mode temperature detection level T_{ALM}. For example, when the data of FIG. 6 is preliminarily obtained in an experiment using the MCM power semiconductor device 50, the overheat protection control section 40 can decide the transient mode temperature detection level optionally from the change rate in the duty ratio of the PWM while the overheat protection control is being performed in the DC-DC convertor 100. In this manner, the overheat protection control section 40 sets the value of the transient mode temperature detection level according to the temperature distribution state in the semiconductor device 50, and thereby it becomes possible to prevent the unnecessary overheat protection operation from occurring and to perform highly efficient overheat protection control.

In the DC-DC convertor 100 of the working example, the overheat protection control section 40 performs the above operation. The contents controlled by the overheat protection control section 40 will be explained by the use of the flowchart in FIG. 3. The explanation will be given assuming that the DC-DC convertor 100 has the steady state at the start point.

First, the overheat protection control section 40 calculates the change rate in the duty ratio of the PWM signal in the control circuit 9, which is the abrupt load change parameter (S10).

The overheat protection control section 40 subsequently determines the temperature detection mode by determining whether or not the above change rate in the duty ratio is equal to or higher than a predetermined specified value (S20). This can be performed by the comparison of the output signal of the control circuit 9 with a reference voltage by the use of a comparator circuit or the like, for example. Here, when the change rate in the duty ratio is equal to or higher than the specified value, the overheat protection control section 40 determines that the temperature detection mode, in which the overheat protection control section detects the temperature of the IC part temperature measurement point using the IC part temperature detection element 11, is the transient mode. Otherwise, the temperature detection mode is determined to be the steady mode.

When the temperature detection mode is determined to be the transient mode, the overheat protection control section 40 decides the transient mode temperature detection level T_{ALM} according to the change rate in the duty ratio of the PWM signal which is the abrupt load change parameter (S30). At this time, the transient mode temperature detection level can be decided by a method of preliminarily obtaining experimental data associating the change rate in the duty ratio of the PWM signal and the transient mode temperature detection level with each other as described above to prepare a relational formula thereof. Alternatively, instead of the above relational formula, the overheat protection control section 40 may decide the transient mode temperature detection level according to a correspondence table preliminarily stored in a storage unit for the change rate in the duty ratio of the PWM signal and the transient mode temperature detection level. By the decision of the above transient mode temperature detection level (S30), it becomes possible to set the most appropriate transient mode temperature detection level suitable for the temperature distribution and to perform highly efficient overheat protection control. When the above decision (S30) is performed optionally, the temperature detection level is readjusted to be the most appropriate, and thereby it is possible to perform further highly efficient overheat protection control.

Subsequently, the overheat protection control section 40 compares a temperature T_{IC} measured by the IC part temperature detection element 11 with the transient mode temperature detection level T_{ALM} (S40). Here, when the temperature T_{IC} measured by the IC part temperature detection element 11 is higher than the transient mode temperature detection level T_{ALM}, the overheat protection control section 40 outputs the overheat protection signal and the control circuit 9 performs the overheat protection operation so as to cause the current in the high-side MOSFET 1 to be cut off (S50), and otherwise determines that the overheat protection operation by the control circuit 9 is not necessary and the process returns to the starting state.

When the temperature detection mode is determined to be the steady mode in the determination whether or not change rate of the duty ratio of the PWM signal is equal to or higher than the predetermined specified value (S20), the overheat protection control section 40 compares the temperature T_{IC} measured by the IC part temperature detection element 11 with the steady mode temperature detection level T_{TSD} (S60). Here, when the temperature T_{IC} measured by the IC part temperature detection element 11 is higher than the steady mode temperature detection level T_{TSD}, the overheat protection control section 40 outputs the overheat protection signal and the control circuit 9 performs the overheat protection operation (S50). Otherwise, the process returns to the starting state.

The overheat protection control section 40 performs the above described control contents in the series of the steps (S10 to S60). The overheat protection control section 40 may be provided with units performing the control content in each of the steps S10 to S60, and may have an arithmetic processing part that performs the transmission and reception of signals with these units and causes the control contents in the respective units to be performed in a specific order. Alternatively, the overheat protection control section 40 may be provided with the control content in each of the steps as respective functions.

In the working example, as described above, first the overheat protection control section 40 determines whether the temperature detection mode by the use of the IC part temperature detection element 11 is the steady mode or the transient mode. In the steady mode the overheat protection control section 40 outputs the overheat protection signal and the control circuit 9 performs the overheat protection operation when the temperature measured by the IC part temperature detection element 11 reaches the steady mode temperature detection level. In the transient mode the overheat protection control section 40 outputs the overheat protection signal and the control circuit 9 performs the overheat protection operation when the temperature measured by the IC part temperature detection element 11 reaches the transient mode temperature detection level. The abrupt load change parameter is used for the determination whether the temperature detection mode is the steady mode or the transient mode. Further, the transient mode temperature detection level is optionally set according to the change of the abrupt load change parameter value and set to be lower as the abrupt load change parameter has a larger value. Thereby, the temperature detection level at which the overheat protection operation is performed is readjusted each time according to the change of the temperature distribution within the semiconductor device 50 in the transient state, resulting in the reduction of the operation rate down caused by the too frequent overheat protection operation. As described above, the temperature detection mode is switched to be performed between the steady mode and the transient mode by the use of the abrupt load change parameter and the transient mode temperature detection level is changed according to the abrupt load change parameter value, and thereby highly efficient and reliable overheat protection control is realized compared to the case in which the temperature detection mode is performed only in the steady mode.

In the working example, the abrupt load change parameter is the change rate in the duty ratio of the PWM signal. In the DC-DC convertor 100 of the working example, the overheat protection control section 40 performs the above control contents and thereby the power semiconductor device 50 is prevented from being broken down by the abrupt heat up even when the load changes abruptly.

Note that, while the working example performs the overheat protection operation by using the change rate in the duty ratio of the PWM signal in the control circuit 9 as the abrupt load change parameter, the overheat protection control section 40 can calculate an electric power value from the source-drain voltage and the source-drain current in the high-side MOSFET 1 and use a change rate in this electric power value also as the abrupt load change parameter, for example. The overheat protection control section 40 becomes capable of performing the overheat protection operation quickly when the load has changed abruptly by using the parameter showing an actual drive situation of the high-side MOSFET 1 as the abrupt load change parameter. While the overheat protection control for the abrupt load change in the high-side MOSFET 1 has been explained above, it is possible to consider similar overheat protection control for the low-side MOSFET 2.

### Working example 2

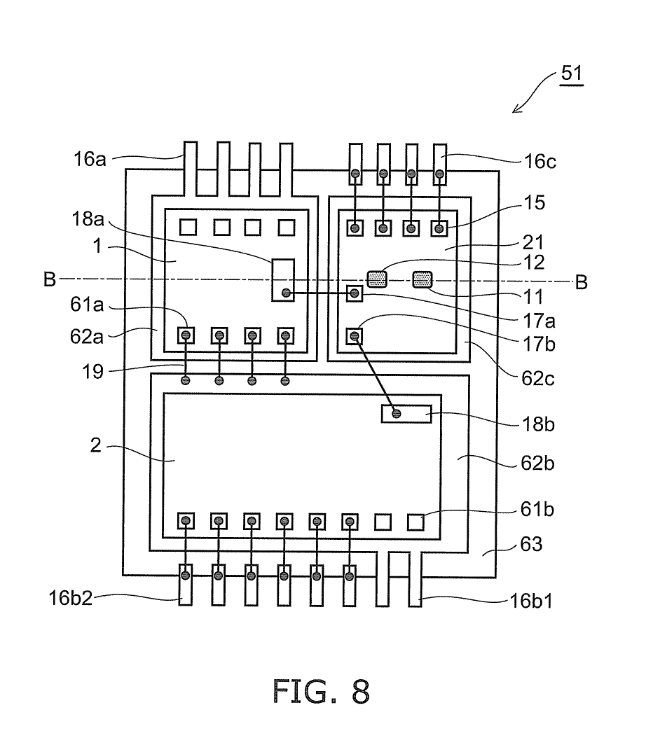

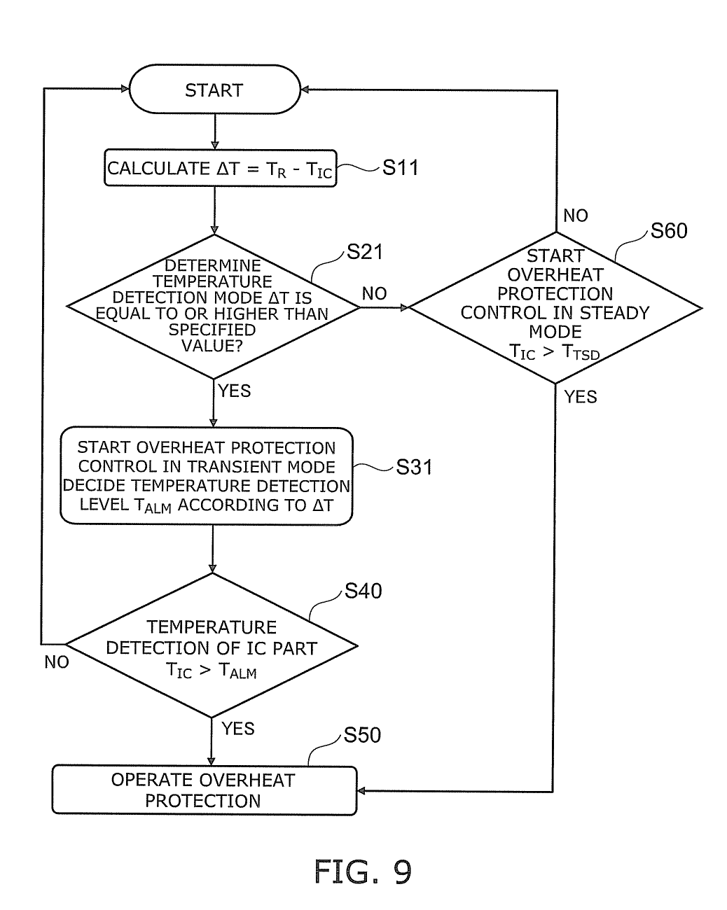

A working example 2 will be described by the use of FIG. 7 to FIG. 11. FIG. 7 is a block diagram showing a main configuration of a DC-DC convertor which is an example of a power semiconductor system of the working example 2. FIG. 8 is a plan view of a power semiconductor device 51 which packages a part of the main configuration of the DC-DC convertor which is an example of the power semiconductor system of the working example 2. FIG. 9 is a flowchart showing the overheat protection control of the DC-DC convertor 200 of the working example 2. Note that the same reference numeral is used for a part having the same configuration as that described in the working example 1 and explanation thereof will be omitted.

As shown in FIG. 7, the DC-DC convertor 200 of the working example 2 includes a first power semiconductor element 1, a second power semiconductor element 2, an input terminal 3 of the DC-DC convertor, an inductor 4, a capacitor 5, an output terminal 7 of the DC-DC convertor, a ground terminal GND, a driver IC 21, a control circuit 9, and an overheat protection control section 41. In the following, a difference from the working example 1 will be described in detail and a similar part will be omitted from the description.

The DC-DC convertor 200 of the working example 2 is different from the DC-DC convertor 100 of the working example 1 in the following point.

While the driver IC 20 of the working example 1 is provided with only the IC part temperature detection element 11 as the temperature detection element, the driver IC 21 of the working example 2 is further provided with a reference part temperature detection element (second temperature detection element) 12 for the high-side MOSFET 1 in addition to the IC part temperature detection element 11. The reference part temperature detection element 12 is disposed on the surface of the driver IC 21 and disposed between the IC part temperature detection element 11 and the high-side MOSFET 1 as shown in FIG. 8 to measure a surface temperature of the driver IC 21. Preferably, the reference part temperature detection element 12 is disposed in the vicinity of the high-side MOSFET 1 on the surface of the driver IC 21. It is desirable to dispose the reference part temperature detection element 12 as close as possible to the high-side MOSFET 1. The reference part temperature detection element 12 is intended to detect a temperature rise ΔT from the IC part temperature detection element toward the high-side MOSFET 1 on the surface of the driver IC 21.

The driver IC 21 supplies each output of the IC part temperature detection element 11 and the reference part temperature detection element 12 to the overheat protection control section 41. For example, as in the working example 1, a part of the lead 16c is electrically connected to the control circuit 9 and another part is electrically connected to the overheat protection control section 41. Each output of the IC part temperature detection element 11 and the reference part temperature detection element 12 is taken out to a part of an input/output electrode pad 15 via an interconnection which is not shown in the drawing and supplied to the overheat protection control section 41 via another part of the lead 16c. Alternatively, the output may be taken out directly to another part of the lead 16c with a bonding wire without via the input/output terminal 15. The overheat protection control section 41 calculates a temperature difference ΔT between a temperature T_{IC} detected by the IC part temperature detection element 11 and a temperature T_{R} detected by the reference part temperature detection element 12 and uses this temperature difference ΔT as the abrupt load change parameter. That is, the working example is different from the working example 1 in the point that the temperature difference ΔT between the temperature T_{IC} detected by the IC part temperature detection element 11 and the temperature T_{R} detected by the reference part temperature detection element 12 is used as the abrupt load change parameter. While the control circuit 9 feeds back the PWM signal to the overheat protection control section 40 in the working example 1, this is not necessary.

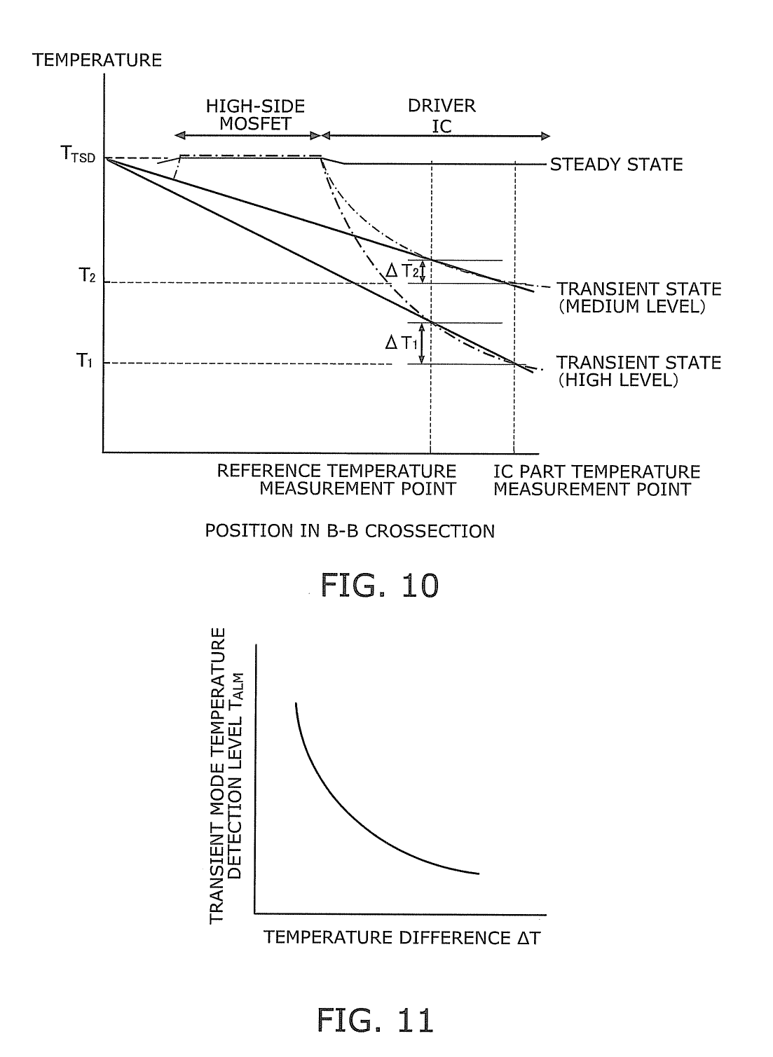

A feature of the overheat protection control in the working example will be explained. FIG. 10 shows temperature distributions from the high-side MOSFET 1 to the driver IC 21 in the B-B direction shown in FIG. 8 for the steady state and the transient state, respectively, when the temperature of the high-side MOSFET 1 reaches the upper limit control temperature. Note that the temperature distribution denoted by Transient state (high level) in the drawing shows a state in which the load changes more abruptly than in the temperature distribution in Transient state (medium level) and induces an abrupt temperature rise in the part of the high-side MOSFET 1. The temperature difference ΔT between the IC part temperature detection element 11 and the reference part temperature detection element 12 in both of the transient states are denoted by ΔT₁ and ΔT₂, respectively. In the steady state, the steady mode temperature detection level is a temperature approximately the same as the upper limit control temperature T_{TSD} for the high-side MOSFET 1 as in the working example 1. The overheat protection control section 41 sets T₁ and T₂ as the transient mode temperature detection levels for Transient state (high level) and Transient state (medium level), respectively.

In the working example, the abrupt load change parameter is the temperature difference ΔT between the IC part temperature detection element 11 and the reference part temperature detection element 12. The temperature difference ΔT between the IC part temperature detection element 11 and the reference part temperature detection element 12 changes according to the abrupt load change state, and the abrupt load change parameter of the working example changes by the abrupt load change as the abrupt load change parameter of the working example 1. Then, the transient mode temperature detection level is set to be lower as the abrupt load change parameter value is larger. That is, as the temperature difference ΔT between the IC part temperature detection element 11 and the reference part temperature detection element 12 is larger, the transient mode temperature detection level is set to be lower. FIG. 11 shows a graph of a relationship between the transient mode temperature detection level T_{ALM} and the temperature difference ΔT between the IC part temperature detection element 11 and the reference part temperature detection element 12. As the first working example, the working example preliminarily obtains experimental data associating the temperature difference ΔT between the IC part temperature detection element 11 and the reference part temperature detection element 12 and the transient mode temperature detection level with each other to prepare a relational formula thereof, and thereby can decide the transient mode temperature detection level. Alternatively, the transient mode temperature detection level can be decided also according to a correspondence table preliminarily stored in a storage unit for the temperature difference ΔT between the IC part temperature detection element 11 and the reference part temperature detection element 12 and the transient mode temperature detection level, instead of the relational formula.

Here, the following relationship is found as the above relational formula. When the temperature difference between the temperature measured by the reference part temperature detection element 12 and the temperature measured by the IC part temperature detection element 11 is denoted by LIT; the steady mode temperature detection level, T_{TSD}; a coefficient, K; and the transient mode temperature detection level, T_{ALM}; respectively, the relationship follows T_{ALM}=T_{TSD}−K·ΔT. Accordingly, the overheat protection control section 41 calculates the temperature difference ΔT from the temperature measured by the reference part temperature detection element 12 and the temperature measured by the IC part temperature detection element 11, both of which temperatures are supplied by the driver IC, and sets the transient mode temperature detection level as needed from the above formula. By using this transient mode temperature detection level, the overheat protection control section 41 can perform the overheat protection control as in the working example 1. In the following, the control contents performed by the overheat protection control section 41 in the DC-DC convertor 200 of the working example will be explained by the use of the flowchart of FIG. 9.

The explanation will be given assuming that the DC-DC convertor 200 has the steady state at the start point. First, the overheat protection control section 41 calculates the temperature difference LIT between the temperature measured by the reference part temperature detection element 12 and the temperature measured by the IC part temperature detection element 11, which is the abrupt load change parameter (S11).

Next, the overheat protection control section 41 determines whether or not the change amount in the above temperature difference ΔT is equal to or larger than a predetermined specified value (S21). Here, when the change amount is equal to or larger than the specified value, the overheat protection control section 41 sets the mode of detecting a temperature in the IC part temperature detection element 11 to be the transient mode. Otherwise, the overheat protection control section 41 sets the steady mode. The determination whether the above temperature difference ΔT is equal to or larger than the specified value or not can be performed by comparison between a reference voltage and ΔT using a comparator, for example.

When the temperature detection mode is determined to be the transient mode, the overheat protection control section 41 decides the transient mode temperature detection level T_{ALM} according to the temperature difference ΔT which is the abrupt load change parameter (S31). At this time, the experimental data associating the temperature difference ΔT and the transient mode temperature detection level with each other is preliminarily obtained and the relational formula thereof is prepared as described above, and thereby the overheat protection control section 41 can decide the transient mode temperature detection level. As an example of the relational formula, as described above, when the temperature difference between the temperature measured by the reference part temperature detection element 12 and the temperature measured by the IC part temperature detection element 11 is denoted by ΔT; the steady mode temperature detection level, T_{TSD}; a coefficient, K; and the transient mode temperature detection level, T_{ALM}; respectively, T_{ALM}=T_{TSD}−K·ΔT is used. Alternatively, the overheat protection control section 41 may decide the transient mode temperature detection level according to the correspondence table preliminarily stored in the storage unit for the temperature difference ΔT and the transient mode temperature detection level T_{ALM}, instead of the above relational formula. By the decision of the above transient mode temperature detection level (S31), the most appropriate transient mode temperature detection level is set according to the temperature distribution within the power semiconductor device 51 and highly efficient overheat protection control becomes possible. Further, when the decision of the transient mode temperature detection level (S31) is optionally performed, the transient mode temperature detection level is optionally readjusted most appropriately and thereby further highly efficient overheat protection control becomes possible.

Subsequently, the temperature T_{IC} measured by the IC part temperature detection element 11 and the decided transient mode temperature detection level T_{ALM} are compared (S40). Here, when the temperature measured by the IC part temperature detection element 11 is higher than the transient mode temperature detection level, the overheat protection control section 41 outputs the overheat protection signal and the control circuit 9 performs the overheat protection operation so as to cut off the current in the high-side MOSFET 1 (S50), and otherwise determines that the overheat protection operation is not necessary and the process returns to the starting state.

When the temperature detection mode is determined to be the steady mode in the determination whether or not the above temperature difference ΔT is equal to or larger than the specified value (S21), the temperature T_{IC} measured by the IC part temperature detection element 11 and the steady mode temperature detection level T_{TSD} are compared (S60). Here, when the temperature T_{IC} measured by the IC part temperature detection element 11 is higher than the steady mode temperature detection level T_{TSD}, the overheat protection control section 41 outputs the overheat protection signal and the control circuit 9 performs the overheat protection operation (S50). Otherwise, the process returns to Step 0 which is the staring state.

The overheat protection control section 41 performs the control contents of the series of steps described above (S11, S21, S31, S40, S50, and S60). The overheat protection control section 41 may be provided with units performing the control contents of respective steps S11, S21, S31, S40, S50, and S60, perform transmission and reception of signals with these units, and include an arithmetic processing part causing the control contents of respective units to be performed in a specific order. Alternatively, the overheat protection control section 41 may be provided with the control contents in respective steps as functions.

As described above, in the working example, as in the working example 1, the overheat protection control section determines whether the temperature detection mode of the IC part temperature detection element 11 at the IC part temperature measurement point is the steady mode or the transient mode. In the steady mode, the overheat protection control section 41 outputs the overheat protection signal and the control circuit 9 performs the overheat protection operation. In the transient mode, the overheat protection control section 41 outputs the overheat protection signal and the control circuit performs the overheat protection operation when the temperature measured by the IC part temperature detection element 11 reaches the transient mode temperature detection level. The determination whether the temperature detection mode is the steady mode or the transient mode is performed by the use of the abrupt load change parameter. Further, the transient mode temperature detection level is optionally set according to the change of the abrupt load change parameter value and set to be lower as the abrupt load change parameter value is larger. Thereby, the temperature detection level at which the overheat protection operation is performed is readjusted according to the change of the temperature distribution in the transient state, resulting in the reduction of the operation rate down caused by the too frequent overheat protection operation. As described above, the temperature detection mode is switched to be performed between the steady mode and the transient mode by the use of the abrupt load change parameter value and the transient mode temperature detection level is changed according to the abrupt load change parameter value, and thereby highly efficient and reliable overheat protection control is realized compared to the case in which the temperature detection mode is performed only in the steady mode.

In the working example, the abrupt load change parameter is the temperature difference ΔT between the temperature measured by the reference part temperature detection element 12 and the temperature measured by the IC part temperature detection element 11. Also in the DC-DC convertor 200 of the working example, the overheat protection control section 41 performs the above control contents and thereby it is possible to prevent the power semiconductor device 50 from being broken down due to the abrupt heat up even when the load changes abruptly. In the case where the temperature around the package is high, the relationship between T₁ and T₂ and the relationship between ΔT₁ and ΔT2 also change. Also in this case, it is possible to calculate the MOSFET operation by preliminary incorporating a calculation equation with consideration for thermal conductivity of the package, and this allows precise overheat protection operation to be performed. Further, while an example, in which the overheat protection control against the abrupt load change is performed for the high-side MOSFET 1, has been explained in the working example, it is possible to perform the overheat protection control similarly also for the low-side MOSFET 2.

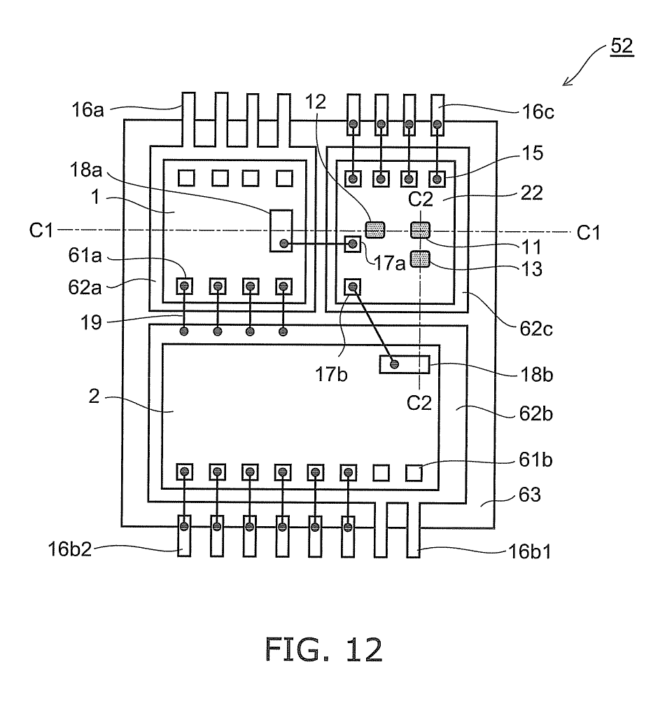

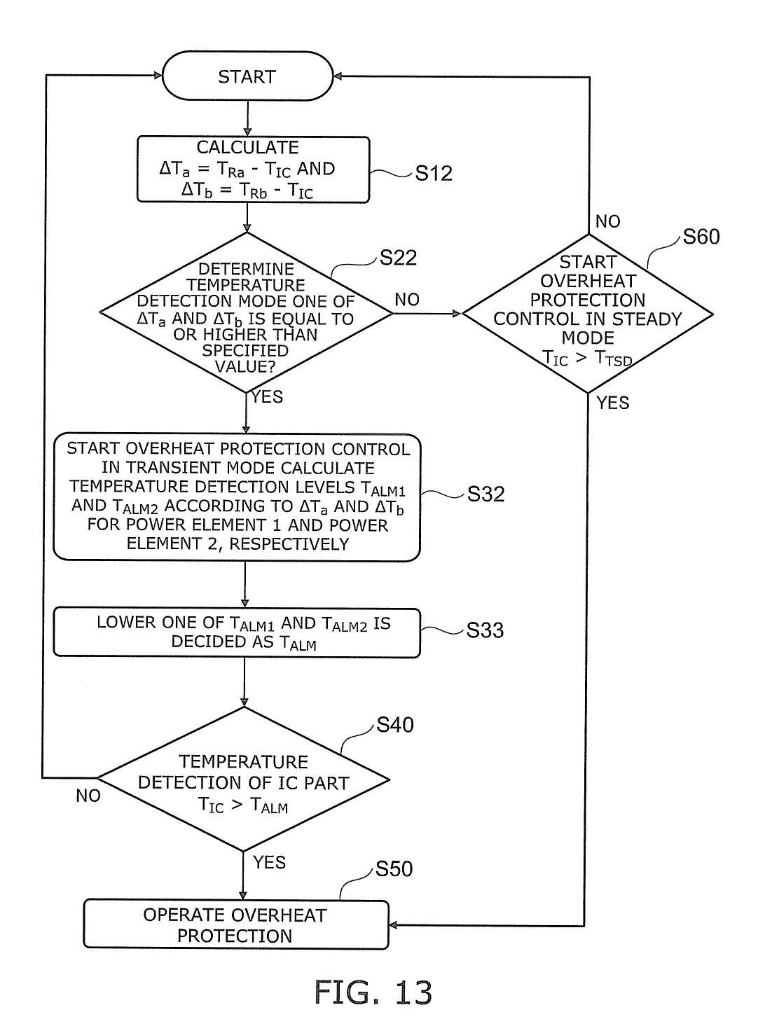

Next, a variation of the working example will be explained. Also in the variation of the working example, a point different from the working example 2 will be explained with respect to the working example 2 and explanation will be omitted regarding a similar configuration part. FIG. 12 is a plan view of a power semiconductor device 52 packaging a part of a main configuration of a DC-DC convertor which is an example of a power semiconductor system in the variation of the working example 2. FIG. 13 is a flowchart of the overheat protection control in the DC-DC convertor 201 of the variation.

The DC-DC convertor 201 of the variation is different from the DC-DC convertor 200 of the working example 2 in the following point. As shown in FIG. 12, the DC-DC convertor 201 of the variation is further provided with a reference part temperature detection element 13 (third temperature detection element) for the low-side MOSFET 2 which is disposed on the surface of a driver IC 22 between the low-side MOSFET 2 and the IC part temperature detection element 11. That is, the DC-DC convertor 201 of the variation is provided with the IC part temperature detection element 11 (first temperature detection element), the reference part temperature detection element 12 for the high-side MOSFET 1 (second temperature detection element), and the reference part temperature detection element 13 for the low-side MOSFET 2 (third temperature detection element) on the surface of the driver IC 22. This reference part temperature detection element 13 for the low-side MOSFET 2 is disposed on the surface of the driver IC 22 as the reference part temperature detection element 12 for the high-side MOSFET 1 in the working example 2, and disposed between the IC part temperature detection element 11 and the low-side MOSFET 2 to measure the surface temperature of the driver IC 22. The reference part temperature detection element 13 is preferably disposed in the vicinity of the low-side MOSFET 2 on the surface of the driver IC 22 and desirably disposed as close as possible to the low-side MOSFET 2. The reference part temperature detection element 13 for the low-side MOSFET can detect a temperature rise ΔT_{b} on the surface of the driver IC 22 from the IC part temperature detection element 11 toward the low-side MOSFET 2 along the direction C2-C2 of FIG. 12. The reference part temperature detection element 12 for the high-side MOSFET 1 can detect a temperature rise ΔTₐ on the surface of the driver IC 22 from the IC part temperature detection element 11 toward the high-side MOSFET 1 along the direction C1-C1 of FIG. 12 as in the working example 2.

The driver IC 22 supplies each output of the IC part temperature detection element 11, the reference part temperature detection element 12 for the high-side MOSFET 1, and the reference part temperature detection element 13 for the low-side MOSFET 2 to the overheat protection control section 42. For example, as in the working example 1, a part of a lead 16c is electrically connected to the control circuit 9 and another part is electrically connected to the overheat protection control section 42. Each output of the IC part temperature detection element 11, and the reference part temperature detection element 12 for the high-side MOSFET 1, and the reference part temperature detection element 13 for the low-side MOSFET 2 is taken out to a part of an input/output electrode pad 15 via an interconnection which is not shown in the drawing and supplied to the overheat protection control section 42 via another part of the lead 16c. Alternatively, the output may be taken out directly to another part of the lead 16c with a bonding wire without via the input/output terminal 15.

The flowchart of the overheat protection control performed by the overheat protection control section 42 (not shown in the drawing) in the DC-DC convertor 201 of the variation is different from the flowchart of the working example 2 shown in FIG. 9 in the following point as shown in FIG. 13. While the temperature difference ΔTₐ between the temperature T_{Ra} measured by the reference part temperature detection element 12 and the temperature T_{IC} measured by the IC part temperature detection element 11 has been calculated for the high-side MOSFET 1 (S11), the temperature difference ΔT_{b} between a temperature T_{Rb} measured by the reference part temperature detection element 13 and the temperature T_{IC} measured by the IC part temperature detection element 11 is calculated also for the low-side MOSFET 2 (S12). Next, while it has been determined whether or not the temperature difference ΔTₐ is equal to or higher than the specified value only for the high-side MOSFET 1 (S21), it is further determined whether or not the temperature difference ΔT_{b} is equal to or higher than a specified value for the low-side MOSFET 2. Both of the determinations use respective specified values and it is determined whether at least one of the temperature differences exceeds the corresponding specified value or not (S22). After that, the transient mode temperature detection level is not decided only for the high-side MOSFET 1 (S31) but a transient mode temperature detection level T_{ALM1} for the high-side MOSFET 1 and a transient mode temperature detection level T_{ALM2} for the low-side MOSFET 2 are calculated (S32). Then, the lower one between T_{ALM1} and T_{ALM2} is further decided to be the transient mode temperature detection level T_{ALM} (533). Regarding the control except the above control contents, the same control contents as those in the working example 2 are performed.

In the following, the overheat protection control to be performed by the overheat protection control section 42 will be explained with reference to the flowchart shown in FIG. 13. The explanation will be given assuming that the DC-DC convertor 201 has the steady state at the start point. First, the overheat protection control section 42 calculates the temperature difference ΔTₐ between the temperature T_{Ra} measured by the reference part temperature detection element 12 for the high-side MOSFET 1 and the temperature T_{IC} measured by the IC part temperature detection element 11, and further calculates the temperature difference ΔT_{b} between the temperature T_{Rb} measured by the reference part temperature detection element 13 for the low-side MOSFET 2 and the temperature T_{IC} measured by the IC part temperature detection element 11 (S12), as the abrupt load change parameters.

It is determined whether or not at least one of the temperature differences ΔTₐ and ΔT_{b} is equal to or larger than the corresponding predetermined specified value (S22). Here, when either of the temperature differences ΔTₐ and ΔT_{b} is equal to or higher than the corresponding specified value, the overheat protection control section 42 determines that the mode detecting the temperature by the use of the IC part temperature detection element is the transient mode. Otherwise, the mode is determined to be the steady mode.

When the temperature detection mode is determined to be the transient mode in the determination whether or not either of ΔTₐ and ΔT_{b} is equal to or larger than the corresponding specified value (S22), the overheat protection control section 42 decides the transient mode temperature detection levels T_{ALM1} and T_{ALM2} according to the respective temperature differences ΔTₐ and ΔT_{b} which are the abrupt load change parameters (S32). At this time, experimental data is preliminarily obtained for associating the temperature difference ΔT and the transient mode temperature detection level with each other and a relational formula thereof is prepared for each of the high-side MOSFET 1 and the low-side MOSFET 2 as shown in FIG. 10 and FIG. 11 of the working example 2, and thereby the transient mode temperature detection level can be decided. As an example of the relational formula, as in the working example 2, when the temperature difference between the temperature measured by the reference part temperature detection element 12 and the temperature measured by the IC part temperature detection element 11 is denoted by ΔTₐ; the steady mode temperature detection level, T_{TSDa}; a coefficient, Kₐ; and the transient mode temperature detection level, T_{ALM1}; respectively, T_{ALM1}=T_{TSDa}−Kₐ·ΔTₐ is used for the high-side MOSFET 1. Further, when the temperature difference between the temperature measured by the reference part temperature detection element 13 and the temperature measured by the IC part temperature detection element 11 is denoted by ΔT_{b}; the steady mode temperature detection level, T_{TSDb}; a coefficient, K_{b}; and the transient mode temperature detection level, T_{ALM2}; respectively, T_{ALM2}=T_{TSDb}−K_{b}·ΔT_{b} is used similarly also for the low-side MOSFET 2. Alternatively, the transient mode temperature detection level can be also decided according to a correspondence table preliminarily stored in the storage unit for the temperature difference ΔT and the transient mode temperature detection level for each of the high-side MOSFET 1 and the low-side MOSFET 2, instead of the above relational formula. By the decision of the above transient mode temperature detection level (S32), the most appropriate transient mode temperature detection level is set according to the temperature distribution within the power semiconductor device 51 and highly efficient overheat protection control becomes possible. Further, when the overheat protection control section 42 optionally decides the transient mode temperature detection level (S32), the transient mode temperature detection level is optionally readjusted most appropriately and thereby further highly efficient overheat protection control becomes possible.

Subsequently, the overheat protection control section 42 finally decides one having a lower value between the transient mode temperature detection level T_{ALM1} for the high-side MOSFET 1 and the transient mode temperature detection level T_{ALM2} for the low-side MOSFET 2, which have been decided as described above, to be the transient mode temperature detection level T_{ALM} (S33).

Subsequently, the overheat protection control section 42 compares the temperature T_{IC} measured by the IC part temperature detection element 11 and the transient mode temperature detection level T_{ALM} decided in Step S33 (S40). Here, when the temperature T_{IC} measured by the IC part temperature detection element 11 is higher than the transient mode temperature detection level T_{ALM}, the overheat protection control section 42 outputs the overheat protection signal and the control circuit 9 performs the overheat protection operation so as to cause the current in the high-side MOSFET 1 to be cut off (S50), and otherwise determines that the overheat protection operation is not necessary and the process returns to the starting state.

When the temperature detection mode is determined to be the steady mode, the temperature T_{IC} measured by the IC part temperature detection element 11 is compared to the steady mode temperature detection level T_{TSD} (S60). Note that the steady mode temperature detection level T_{TSD} is one having a lower value between the steady mode temperature detection level T_{TSDa} for the high-side MOSFET 1 and the steady mode temperature detection level T_{TSDb} for the low-side MOSFET 2, which have been decided preliminarily. Here, when the temperature T_{IC} measured by the IC part temperature detection element 11 is higher than the steady mode temperature detection level T_{TSD}, the overheat protection control section 42 outputs the overheat protection signal and the control circuit 9 performs the overheat protection operation (S50). Otherwise, the process returns to the starting state.

The overheat protection control section 42 performs the control contents of the series of steps (S12, S22, S32, S33, S40, S50, and S60) which have been explained above. The overheat protection control section 42 may be provided with units performing the control contents of respective steps S12, S22, S32, S33, S40, S50, and S60, perform transmission and reception of signals with these units, and include an arithmetic processing part causing the control contents in the respective units to be performed in a specific order. Alternatively, the overheat protection control section 42 may be provided with the control contents in respective steps as functions.

As described above, the variation also determines whether the temperature detection mode of the IC part temperature detection element 11 at the IC part temperature measurement point is the steady mode or the transient mode, as in the working example 1. The overheat protection control section 42 outputs the overheat protection signal and the control circuit 9 performs the overheat protection operation when the temperature measured by the IC part temperature detection element reaches the steady mode temperature detection level in the steady mode or the transient temperature detection level in the transient mode. The abrupt load change parameter is used for the determination whether the temperature detection mode is the steady mode or the transient mode. Further, the transient mode temperature detection level is optionally set according to the value of the abrupt load change parameter and set to be lower as the abrupt load change parameter value is larger. Thereby, the temperature detection level for the overheat protection control operation is readjusted each time according to the change of the temperature distribution in the transient state, resulting in the reduction of the operation rate down caused by the too frequent overheat protection operation. As described above, the temperature detection mode is switched to be performed between the steady mode and the transient mode by the use of the abrupt load change parameter and the transient mode temperature detection level is changed according to the abrupt load change parameter value, and thereby highly efficient and reliable overheat protection control is realized compared to the case in which the temperature detection mode is performed only in the steady mode.

In the variation, the abrupt load change parameter is the temperature difference ΔT between the temperature measured by the reference part temperature detection element and the temperature measured by the IC part temperature detection element 11 for each of the high-side MOSFET 1 and the low-side MOSFET 2. Also in the DC-DC convertor 201 of the variation, the overheat protection control section 42 performs the above control contents, and thereby it is possible to prevent the power semiconductor device 52 from being broken down due to the abrupt heat up even when the load changes abruptly.

### Working example 3

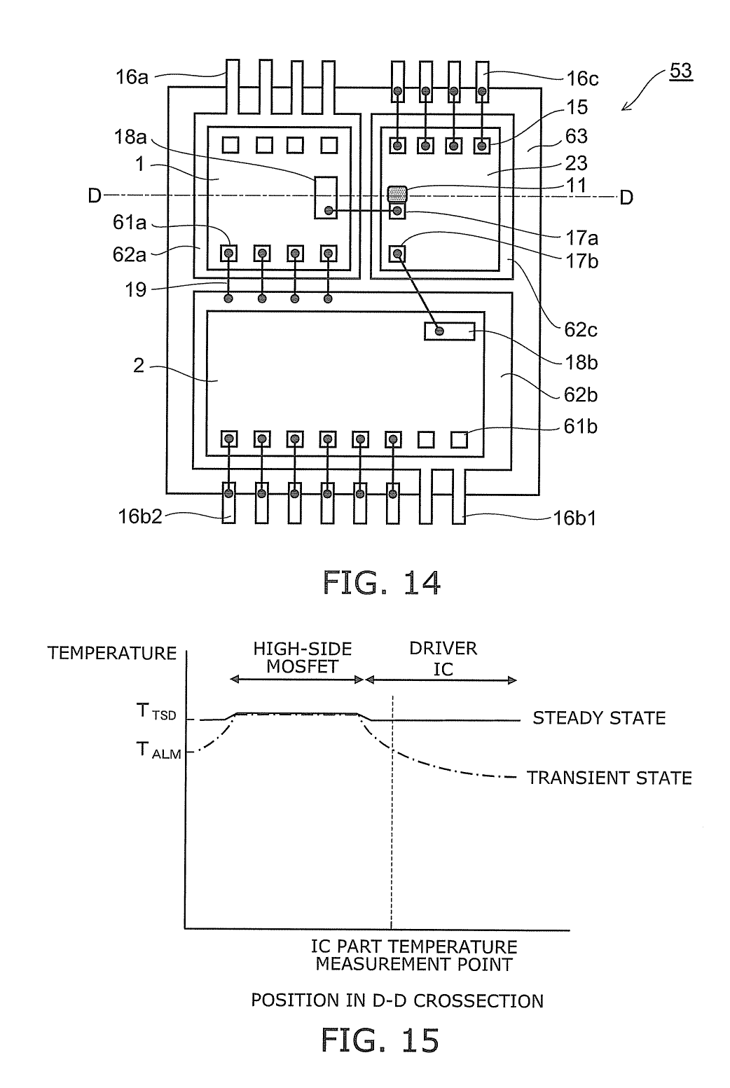

A DC-DC convertor 300 of a working example 3 will be explained. Note that a part having the same configuration as the configuration explained in the working example 1 is denoted by the same reference numeral and explanation thereof will be omitted. The DC-DC convertor 300 which is an example of a power semiconductor system of the working example 3 is different from that of the working example 1 in a power semiconductor device 53 which is an MCM including the elements within the same resin package. The configuration of the DC-DC convertor is the same as that of the working example 1 shown in FIG. 1, and the flow of the overheat protection control is also the same as that of the working example 1 shown in FIG. 3. FIG. 14 shows a plan view of the power semiconductor device 53 of the working example.

The DC-DC convertor 300 of the working example is different from the DC-DC convertor 100 of the working example 1 in the following point. The working example is different from the working example 1 in the point that an IC part temperature detection element 11 is disposed to neighbor a gate output electrode pad 17a electrically connected to a gate electrode pad 18a of the high-side MOSFET 1 on the surface of a driver IC 23. FIG. 15 shows a temperature distribution from the driver IC 23 to the high-side MOSFET 1 along the D-D direction of FIG. 14. The driver IC 23 supplies the output of the IC part temperature detection element 11 to an overheat protection control section 40. For example, as in the working example 1, a part of a lead 16c is electrically connected to a control circuit 9 and another part is electrically connected to the overheat protection control section 40. The output of the IC part temperature detection element 11 is taken out to a part of an input/output electrode pad 15 via an interconnection which is not shown in the drawing and supplied to the overheat protection control section 40 via another part of the lead 16c. Alternatively, the output of the IC part temperature detection element 11 may be taken out directly to another part of the lead 16c with a bonding wire without via the input/output electrode pad 15. This is the same in a variation of the working example.

In the working example, the IC part temperature detection element 11 is disposed at a side closer to the high-side MOSFET 1 compared to the case shown in FIG. 2 of the working example 1. Further, the IC part temperature detection element 11 is disposed to neighbor the gate output electrode pad 17a. Even when the load changes abruptly to induce the transient state, the heat abruptly generated in the high-side MOSFET 1 is transferred to the driver IC 23 through a gate electrode pad 18a of the high-side MOSFET 1, a bonding wire 19, and the gate output electrode pad 17a on the driver IC 23. Accordingly, it is possible to reduce a temperature difference between the temperature in the part of the driver IC 23 measured by the IC part temperature detection element 11 and the temperature in the part of the high-side MOSFET 1 compared to that in the working example 1. As a result, regardless whether in the transient state or in the steady state, it is possible to operate the DC-DC convertor at a temperature equal to or lower than the upper limit control temperature of the high-side MOSFET even when the overheat protection control section 40 is provided with only the steady mode as the temperature detection mode. Highly efficient and reliable overheat protection control can be realized. That is, the DC-DC convertor may perform only the temperature detection in S60 and the overheat protection operation in S50 of the working example 1 shown in FIG. 3. However, the DC-DC convertor of the working example can set the transient mode temperature detection level to be higher than that in the working example 1 by employing a configuration similar to that of the working example 1. As a result, it is possible to realize overheat protection control having a further higher operation efficiency and reliability than that of the working example 1.

Note that, while the description has been given for the example in which the power semiconductor device 53 of the working example is applied to the DC-DC convertor 100 having the overheat protection control of the working example 1, it is possible to apply the power semiconductor device 53 of the working example to the DC-DC convertor 200 of the working example 2 and the DC-DC convertor 201 of the variation thereof.

Further, while the IC part temperature detection element 11 is provided to neighbor the gate output electrode pad 17a, the IC part temperature detection element 11 may be provided so as to be sandwiched between the gate output electrode pad 17a and the surface of the driver IC 24 as shown in the variation of the working example to be described below.

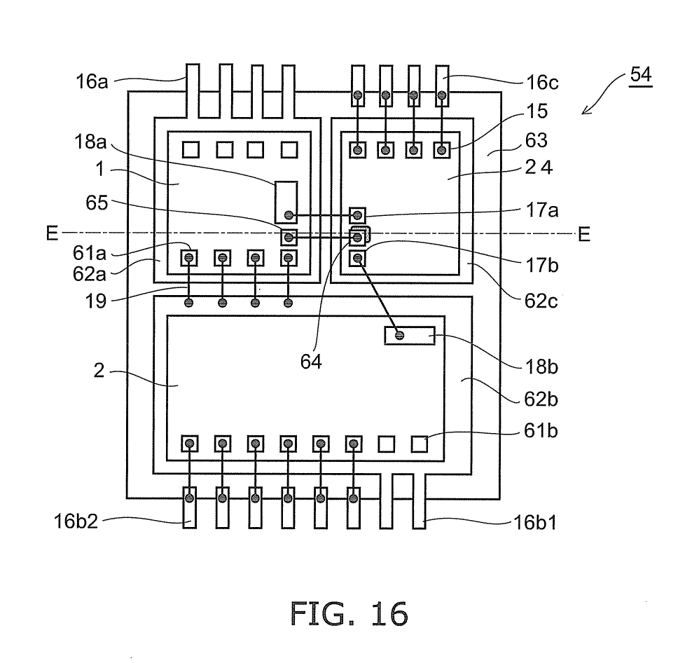

Next, the variation of the working example will be described. FIG. 16 shows a plan view of a power semiconductor device 54 of a DC-DC convertor 301 of the variation. The DC-DC convertor 301 of the variation is different from the DC-DC convertor 300 of the working example 3 in the following point. The DC-DC convertor 301 of variation is further provided with a heat radiation pad 65 (first metal pad) made of metal in addition to the gate pad 18a on the surface of the high-side MOSFET 1 and provided with a heat reception pad 64 (second metal pad) in addition to the gate output pad 17a on the surface of the driver IC 24. These heat radiation pad 65 and heat reception pad 64 are electrically connected to each other with a bonding wire 19. As the heat is transferred from the high-side MOSFET 1 to the driver IC 24 through the gate electrode pad 18a, the bonding wire 19, and the gate output electrode pad 17a, the heat is transferred from the high-side MOSFET 1 to the driver IC 24 through the heat radiation pad 65, the bonding wire 19, and the heat reception pad 64. Each of these heat radiation pad 65 and heat reception pad 64 does not to have current flowing therein, and thereby may be insulated from the other electrodes of the high-side MOSFET 1 and the driver IC 24. The IC part temperature detection element 11 is disposed to be sandwiched between the surface of the driver IC 24 and the heat reception pad 64.

Except the above described point, the configuration of the DC-DC convertor of the variation is the same as that of the DC-DC convertor of the working example 3. That is, as in the working example 3, the DC-DC convertor 301 is provided with a configuration similar to that of the working example 1 except the IC part temperature detection element 11, and thereby can have a further higher transient mode temperature detection level than in the working example 1. As a result, it is possible to realize overheat protection control having a further higher efficiency and reliability than that of the working example 1. While the description has been given for an example in which the DC-DC convertor 100 having the overheat protection control of the working example 1 includes the power semiconductor device 54 of the variation, the DC-DC convertor 200 of the working example 2 and the DC-DC convertor 201 of the variation thereof can include the power semiconductor device 54 of the variation. In the variation, the heat is transferred from the high-side MOSFET 1 to the driver IC 24 through the heat radiation pad 65, the bonding wire 19, and the heat reception pad 64, and thereby it is possible to further reduce the temperature difference between the temperature in the part of the drive IC 24 measured by the IC part temperature detection element 11 and the temperature in the part of the high-side MOSFET 1 compared to the working example 3. Also in the variation, as the working example 2, it is possible to operate the DC-DC convertor at a temperature equal to or lower than the upper limit control temperature of the high-side MOSFET regardless whether in the transient state or in the steady state, even when the overheat protection control section 40 is provided with only the steady mode as the temperature detection mode.

While an example of performing the overheat protection control against the abrupt load change for the high-side MOSFET 1 has been described in the working example and variation, the overheat protection control can be performed similarly also for the low-side MOSFET 2. In FIG. 14 an FIG. 16, the gate pad 18a on the surface of the high-side MOSFET 1 and the output pad 17a on the surface of the driver IC24 are electrically connected via the bonding wire 19, however electrical connection by materials with high thermal conductivity in a ribbon shape or a plate shape is also possible. The connection between the heat radiation pad 65 on the surface of the high-side MOSFET 1 and the heat reception pad 64 on the surface of the IC driver 24 is the same as the above. In this manner, the connection is performed by using the materials with high thermal conductivity (for example, copper or aluminum) in a ribbon shape or a plate shape and thus the temperature difference between the temperature of the IC drivers 23, 24 measured by the IC part temperature detection element 11 and the temperature of the high-side MOSFET 1 can be further reduced.

While a power semiconductor system of the invention has been described for the DC-DC convertor as an example by the use of working examples and variations, various modifications are possible within a range without departing from the spirit of the invention. Also it is possible to combine the respective working examples and variations used in the description with one another. Further, in each of the above described working examples and variations, the control circuit 9 and each of the overheat protection control sections 40, 41 and 42 have been explained to be provided in the outside of the MCM semiconductor devices 50, 51, 52, 53 or 54 as an example, for the purpose of easily explaining the modes of the invention in the semiconductor system. However, obviously each of the control circuit and the overheat protection control section can be included within the semiconductor device in the same package depending on a design. Alternatively, each of the control circuit and the overheat protection control section also can be formed within the same chip monolithically together with the driver IC.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A power semiconductor system, comprising:
a first power semiconductor element configured to control current flowing between a first electrode and a second electrode with a control electrode;
a driver IC configured to supply a drive signal turning the first power semiconductor element on and off;
a first temperature detection element configured to detect a temperature of the driver IC;
a control circuit configured to supply a control signal for controlling operation of the driver IC to the driver IC; and
an overheat protection control section configured to supply an overheat protection signal to the control circuit based on an output of the first temperature detection element,
the control circuit receiving the overheat protection signal to perform overheat protection operation for protecting the first power semiconductor element, and
the overheat protection control section determining whether a temperature detection mode of the driver IC is a steady mode or a transient mode,
in the steady mode, supplying the overheat protection signal to the control circuit when a temperature measured by the first temperature detection element reaches a steady mode temperature detection level, and
in the transient mode, supplying the overheat protection signal to the control circuit when a temperature measured by the first temperature detection element reaches a transient mode temperature detection level.

2. The system according to claim 1, wherein
the overheat protection control section measures an abrupt load change parameter indicating an abrupt load change state of the first power semiconductor element, determines the temperature detection mode to be the transient mode when the abrupt load change parameter has a value equal to or larger than a specified value, and otherwise determines the temperature detection mode to be the steady mode,
when the temperature detection mode being determined to be the transient mode,
the overheat protection control section decides the transient mode temperature detection level which changes in response to the abrupt load change parameter value, compares the temperature measured by the first temperature detection element and the transient mode temperature detection level, and supplies the overheat protection signal to the control circuit so as to cause the current in the first power semiconductor element to be cut off when determining the measured temperature to be higher than the transient mode temperature detection level, and
when the temperature detection mode being determined to be the steady mode,
the overheat protection control section compares the steady mode temperature detection level having a value which is higher than a value of the transient mode temperature detection level and does not depend on the abrupt load change parameter value with the temperature measured by the first temperature detection element, and supplies the overheat protection signal to the control circuit when the measured temperature is higher than the steady mode temperature detection level.

3. The system according to claim 2, wherein
the driver IC further includes a second temperature detection element,
the second temperature detection element is disposed between the first temperature detection element and the first power semiconductor element, and
the abrupt load change parameter is a temperature difference between a temperature measured by the second temperature detection element and the temperature measured by the first temperature detection element.

4. The system according to claim 3, wherein
the transient mode temperature detection level is decided according to a relational formula representing a relationship between the temperature difference and the transient mode temperature detection level.

5. The system according to claim 4, wherein
the transient mode temperature detection level is decided according to a relational formula,
T_{ALM}=T_{TSD}−K·ΔT
where the temperature difference is denoted by ΔT; the steady mode temperature detection level, T_{TSD}; a coefficient, K, and the transient mode temperature detection level, T_{ALM}.

6. The system according to claim 3, wherein
the transient mode temperature detection level is decided according to a correspondence table stored in a storage unit for the transient mode temperature detection level and the temperature difference between the temperature measured by the second temperature detection element and the temperature measured by the first temperature detection element.

7. The system according to claim 4, further comprising:
a second power semiconductor element; and
a third temperature detection element disposed between the first temperature detection element and the second power semiconductor element,
a second abrupt load change parameter being a second temperature difference between a temperature measured by the third temperature detection element and the temperature measured by the first temperature detection element,
the temperature detection mode being determined to be the transient mode when one of the temperature difference and the second temperature difference is equal to or larger than a specified value, and otherwise determined to be the steady mode,
a second transient mode temperature detection level being decided according to a relational formula representing a relationship between the second temperature difference and a second transient mode temperature detection level, and
a transient temperature mode detection level having a smaller value of the transient mode temperature detection level and the second transient mode temperature detection level being decided to be the transient mode temperature detection level.

8. The system according to claim 5, further comprising:
a second power semiconductor element; and
a third temperature detection element disposed between the first temperature detection element and the second power semiconductor element,
a second abrupt load change parameter being a second temperature difference between a temperature measured by the third temperature detection element and the temperature measured by the first temperature detection element,
the temperature detection mode being determined to be the transient mode when one of the temperature difference and the second temperature difference is equal to or larger than a specified value, and otherwise determined to be the steady mode,
a second transient mode temperature detection level being decided according to a relational formula,
T_{ALM2}=T_{TSD}−K₂·ΔT₂
where the second temperature difference is denoted by ΔT₂, a coefficient, K₂, and the second transient mode temperature detection level, T_{ALM2}, and
a transient mode temperature detection level having a smaller value of the transient mode temperature detection level and the second transient mode temperature detection level being decided to be the transient mode temperature detection level.

9. The system according to claim 6, further comprising:
a second power semiconductor element; and
a third temperature detection element disposed between the first temperature detection element and the second power semiconductor element,
a second abrupt load change parameter being a second temperature difference between a temperature measured by the third temperature detection element and the temperature measured by the first temperature detection element,
the temperature detection mode being determined to be the transient mode when one of the temperature difference and the second temperature difference is equal to or larger than a specified value, and otherwise determined to be the steady mode,
a second transient mode temperature detection level being decided according to a correspondence table between the second temperature difference and a second transient mode temperature detection level, and
a transient temperature mode detection level having a smaller value of the transient mode temperature detection level and the second transient mode temperature detection level being decided to be the transient mode temperature detection level.

10. The system according to claim 2, wherein
the abrupt load change parameter is a change rate in a duty ratio of a pulse signal which is the control signal supplied from the control circuit to the driver IC, and
the transient mode temperature detection level is decided according to a relational formula representing a relationship between the change rate in the duty ratio and the transient mode temperature detection level.

11. The system according to claim 2, wherein
the abrupt load change parameter is a change rate in a duty ratio of a pulse signal which is the control signal supplied from the control circuit to the driver IC, and
the transient mode temperature detection level is decided according to a correspondence table stored in a storage unit for the change rate in the duty ratio and the transient mode temperature detection level.

12. The system according to claim 2, wherein
the abrupt load change parameter is a change rate of electric power which is calculated from a current flowing between the first electrode and the second electrode of the first power semiconductor element and a voltage applied across the first electrode and the second electrode.

13. The system according to claim 2, wherein
the first power semiconductor element further includes a gate pad connected to a gate electrode,
the driver IC further includes a gate output pad outputting a gate signal to the semiconductor element,
the gate pad and the gate output pad are connected with each other with a bonding wire and
the first temperature detection element is disposed to neighbor the gate output pad on a surface of the driver IC or to be sandwiched between the gate output pad and the surface of the driver IC.

14. The system according to claim 2, wherein
the first power semiconductor element further includes a first metal pad and a gate pad connected to a gate electrode,
the driver IC further includes a second metal pad and a gate output pad outputting a gate signal to the semiconductor element,
the gate pad and the gate output pad are connected with each other with a first bonding wire,
the first metal pad and the second metal pad are connected with each other with a second bonding wire, and
the first temperature detection element is disposed to neighbor the second metal pad on a surface of the driver IC or to be sandwiched between the second metal pad and the surface of the driver IC.

15. The system according to claim 5, wherein
the first power semiconductor element further includes a gate pad connected to a gate electrode,
the driver IC further includes a gate output pad outputting a gate signal to the semiconductor element,
the gate pad and the gate output pad are connected with each other with a bonding wire and
the first temperature detection element is disposed to neighbor the gate output pad on a surface of the driver IC or to be sandwiched between the gate output pad and the surface of the driver IC.

16. The system according to claim 5, wherein
the first power semiconductor element further includes a first metal pad and a gate pad connected to a gate electrode,
the driver IC further includes a second metal pad and a gate output pad outputting a gate signal to the semiconductor element,
the gate pad and the gate output pad are connected with each other with a first bonding wire,
the first metal pad and the second metal pad are connected with each other with a second bonding wire, and
the first temperature detection element is disposed to neighbor the second metal pad on a surface of the driver IC or to be sandwiched between the second metal pad and the surface of the driver IC.

17. The system according to claim 8, wherein
the first power semiconductor element further includes a gate pad connected to a gate electrode,
the driver IC further includes a gate output pad outputting a gate signal to the semiconductor element,
the gate pad and the gate output pad are connected with each other with a bonding wire and the first temperature detection element is disposed to neighbor the gate output pad on a surface of the driver IC or to be sandwiched between the gate output pad and the surface of the driver IC.

18. The system according to claim 8, wherein
the first power semiconductor element further includes a first metal pad and a gate pad connected to a gate electrode,
the driver IC further includes a second metal pad and a gate output pad outputting a gate signal to the semiconductor element,
the gate pad and the gate output pad are connected with each other with a first bonding wire,
the first metal pad and the second metal pad are connected with each other with a second bonding wire, and
the first temperature detection element is disposed to neighbor the second metal pad on a surface of the driver IC or to be sandwiched between the second metal pad and the surface of the driver IC.
